(19) United States
(12) Patent Application Publication
(10) Pub. No.: US 2012/0260963 A1
(43) Pub. Date: Oct. 18, 2012

(54) PROTECTIVE CONTAINER

(75) Inventor: MING-MIN LIN, Tu-Cheng (TW)

(73) Assignee: HON HAI PRECISION INDUSTRY CO., LTD., Tu-Cheng (TW)

(21) Appl. No.: 13/117,307

(22) Filed: May 27, 2011

(30) Foreign Application Priority Data
Apr. 13, 2011 (TW) 100112764

(51) Int. Cl. H01L 35/30; H01L 31/042

(52) U.S. Cl. 136/206; 136/205; 136/244

(57) ABSTRACT

A protective container includes a main body, a thermoelectric converting device, and a power storage device. The thermoelectric converting device includes a first converting unit and a second converting unit. The first converting unit is located outside of the main body for converting heat into electrical energy. The second converting unit is received within the main body for converting heat in the main body into electrical energy. The power storage device stores the electrical energy from the thermoelectric converting device, and provides voltages to power electrical devices in the main body.

### BACKGROUND

1. Technical Field

The disclosure generally relates to protective housing, and more particularly to a self-powered protective container.

2. Description of the Related Art

Mobile cloud computing devices are usually received and are secured within corresponding containers for the convenience of transport to remote places, such as a mountain or a desert. The containers are usually made from metal materials, which can easily conduct outside heat into the containers, causing the inside temperature of the containers to gradually increase. Moreover, the cloud computing device themselves can produce a lot of heat during operation, so radiators are needed in the containers to dissipate the heat. However, power sources are sometimes unavailable to power the mobile cloud computing devices and the radiators in the mountain, desert, or other remote areas.

Therefore, there is room for improvement within the art.

### BRIEF DESCRIPTION OF THE DRAWINGS

Many aspects of a protective container can be better understood with reference to the following drawings. The components in the drawings are not necessarily drawn to scale, the emphasis instead being placed upon clearly illustrating the principles of the protective container. Moreover, in the drawings, like reference numerals designate corresponding parts throughout the several views. Wherever possible, the same reference numbers are used throughout the drawings to refer to the same or like elements of an embodiment.

FIG. 1 is a block view of one embodiment of a protective container including a thermoelectric converting device, a photoelectric converting device, and a power storage device.

FIG. 2 is a block connection view of the thermoelectric converting module, the photoelectric converting module, and the power storage module shown in FIG. 1.

### DETAILED DESCRIPTION

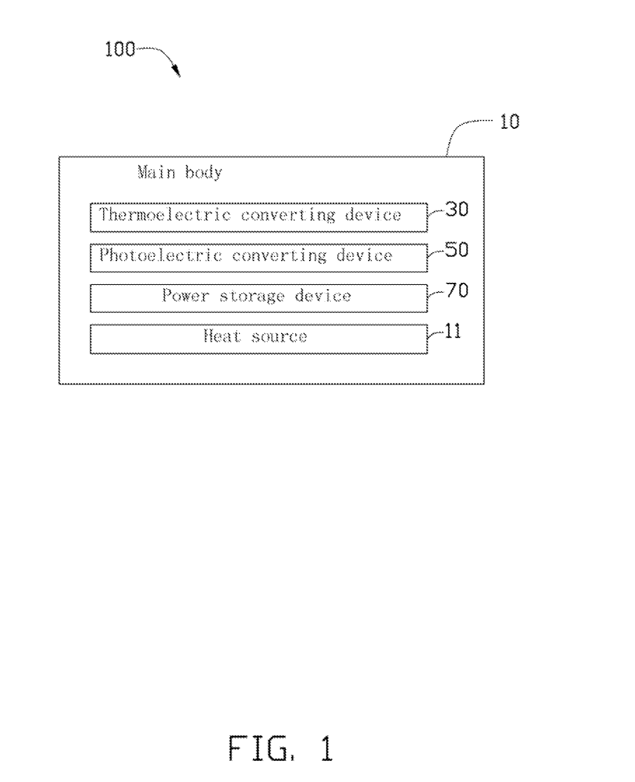

FIG. 1 shows a block view of one embodiment of a protective container 100 including a thermoelectric converting device 30, a photoelectric converting device 50, and a power storage device 70. The protective container 100 is capable of receiving and securing a mobile cloud computing device and automatically converting heat into corresponding electrical energy to power the mobile cloud computing device. The protective container 100 further includes a main body 10.

The thermoelectric converting device 30 is partially located outside the main body 10, and the other part is received in the main body 10. The photoelectric converting device 50 is positioned outside the main body 10. The power storage device 70 is received and is positioned within the main body 10.

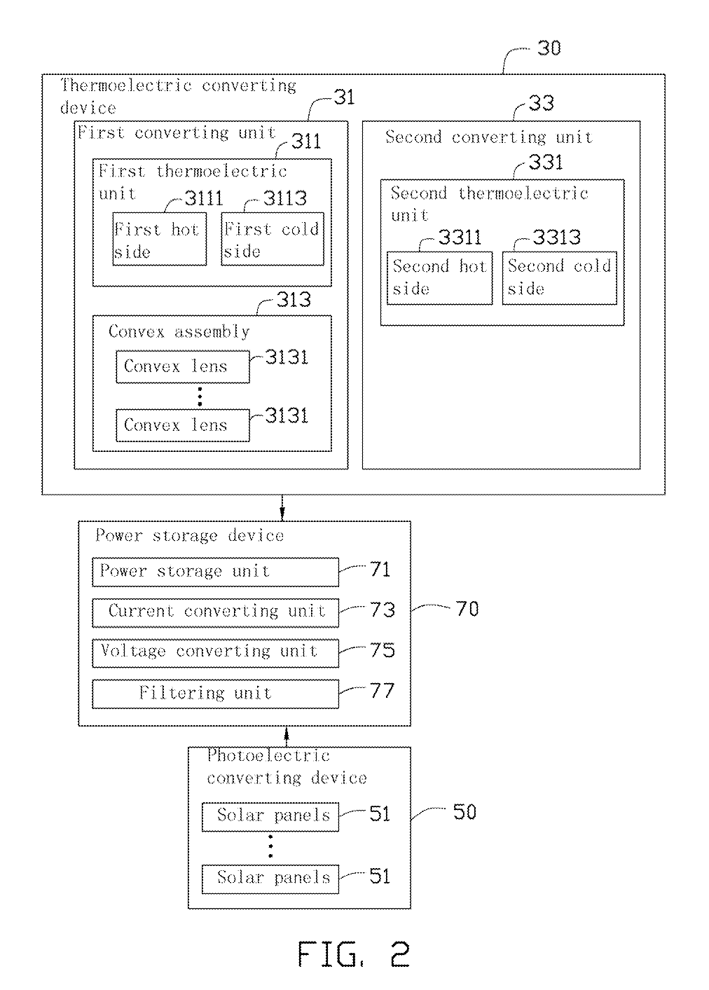

Further referring to FIG. 2, the thermoelectric converting device 30 is capable of directly converting heat to electrical energy. The thermoelectric converting device 30 includes a first converting unit 31 and a second converting unit 33. In this embodiment, the first converting unit 31 is located outside the main body 10 and is capable of converting external heat such as solar energy into corresponding electrical energy. The second converting unit 33 is received and is positioned within the main body 10 and is capable of converting heat generated by the mobile cloud computing device into corresponding electrical energy.

The first converting unit 31 includes a first thermoelectric unit 311 and a convex assembly 313. The first thermoelectric unit 311 can be a thermoelectric converter or be made from thermoelectric materials. In this embodiment, the first thermoelectric unit 311 is made from thermoelectric material and includes a first hot side 3111 and a first cold side 3113. The first hot side 3111 and the first cold side 3113 form a thermocouple consisting of a coupling or junction of dissimilar semiconductors or metals joined, so the two junction surfaces of contact are implemented as the first hot side 3111 and the first cold side 3113, respectively. Hence, a potential difference generated between the junction surfaces of contact is a measurement of the temperature difference between the points through thermoelectric effect.

When there is a temperature difference between the first hot side 3111 and the first cold side 3113, a constant current is created in the first thermoelectric unit 311, forming a current loop. The first thermoelectric unit 311 is mounted on the outer surface of the upper wall of the main body 10. The first hot side 3111 of the first thermoelectric unit 311 is located outside the main body 10 and is aligned with the convex lens assembly 313. The first cold side 3113 of the first thermoelectric unit 311 is installed and is received within the main body 10. The first converting unit 31 is electrically connected to the power storage device 70.

The convex lens assembly 313 includes a plurality of convex lenses 3131, whose foci are aligned with the first hot side 3111 of the first thermoelectric unit 311. The convex lens assembly 313 is located outside the main body 10, converges and focuses incoming light lines to the first hot side 3111, enabling the temperature of the first hot side 3111 to be increased. The temperature of the first hot side 3111 is higher than that of the first cold side 3113, forming a temperature difference between the first hot side 3111 and the first cold side 3113, so the current is generated in the first thermoelectric unit 311, and the electrical energy is stored in the power storage device 70.

The second converting unit 33 includes a second thermoelectric unit 331 electrically connected to the power storage device 70. The main body 10 includes a heat source 11 which can generate a substantial heat during operation, such as a server, memories, or the north bridge chipset of the mobile cloud computing device. In this embodiment, the second thermoelectric unit 331 has substantially the same structure as that of the first thermoelectric unit 311. The second thermoelectric unit 331 includes a second hot side 3311 and a second cold side 3313.

The second hot side 3311 is substantially located on/near the heat source 11 to absorb and gather generated heat. The second cold side 3313 is located away from the heat source 11, thus a temperature difference is formed between the second hot side 3311 and the second cold side 3313. Hence, the second thermoelectric unit 331 generates a constant current, and the electrical energy is stored in the power storage device 70. In this embodiment, the second thermoelectric unit 331 can be a thin-film thermoelectric component. The hot side of the thin-film thermoelectric component is mounted on the heat source 11.

The photoelectric converting device 50 includes a plurality of solar panels 51, which is a packaged interconnected assembly and is used as a component of a large photovoltaic system to generate and supply electrical energy. In this embodiment, the solar panels 51 are located at the outer surface of sidewalls of the main body 11 to use and absorb light energy from the sun to generate electrical energy.

The power storage device 70 includes a power storage unit 71, a current converting unit 73, a voltage converting unit 75, and a filtering unit 77. The power storage unit 71 can be a storage battery and is capable of storing electrical energy from the first converting unit 31 and the second converting unit 33. The current converting unit 73 is electrically connected to the power storage unit 71, which can be an inverter and convert direct current from the thermoelectric converting device 30 and the photoelectric converting device 50 into alternating current.

The voltage converting unit 75 can be a power adapter or a power transformer. The voltage converting unit 75 is electrically connected to the current converting unit 73 and is capable of converting output voltage from the current converting unit 73 into different voltage for different electrical devices. The filtering unit 77 is electrically connected to the voltage converting unit 75 and is capable of rectifying and filtering output current from the voltage converting unit 75 to generate and output a stable current to power the electrical devices in the main body 10.

In summary, in one embodiment of the protective container 100, the first converting unit 31 of the thermoelectric converting device 30 converts external heat of the main body 10 to electrical energy, and the second converting unit 33 converts heat within the main body 10 to electrical energy. Thus, the electrical energy can be stored in the power storage device 70 or power other electrical devices such as the mobile cloud computing device. Moreover, the photoelectric converting device 50 can absorb and convert solar energy into electrical energy to self-power, and the electrical energy from the photoelectric converting device 50 can be stored in the power storage device 70 or power other electrical devices.

In the present specification and claims the word “a” or “an” preceding an element does not exclude the presence of a plurality of such elements. Further, the word “comprising” does not exclude the presence of other elements or steps than those listed.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A protective container, comprising:
a main body;
a thermoelectric converting device comprising:
a first converting unit located outside of the main body converting heat into electrical energy; and
a second converting unit received within the main body converting heat in the main body into electrical energy; and
a power storage device electrically connected to the first converting unit and the second converting unit, wherein the power storage device stores the electrical energy from the thermoelectric converting device, and provides voltage to power electrical devices in the main body.

2. The protective container as claimed in claim 1, wherein the first converting unit comprises a first thermoelectric unit comprising a first hot side and a first cold side, the first hot side of the first thermoelectric unit is located outside the main body, and the first cold side of the first thermoelectric unit is installed and received within the main body.

3. The protective container as claimed in claim 2, wherein the first hot side and the first cold side form a thermocouple consisting of a coupling or junction of dissimilar semiconductors or metals joined, two junction surfaces of contact are respectively implemented as the first hot side and the first cold side, and a temperature difference between the first hot side and the first cold side creates a current in the first thermoelectric unit.

4. The protective container as claimed in claim 2, wherein the first converting unit further comprises a convex lens assembly comprising a plurality of convex lenses, the foci of the convex lenses are aligned with the first hot side of the first thermoelectric unit, the convex lens assembly converges and focuses incoming light lines to the first hot side to increase the temperature of the first hot side thereby forming a temperature difference between the first hot side and the first cold side, so that current is generated in the first thermoelectric unit, and the electrical energy is stored in the power storage device.

5. The protective container as claimed in claim 1, wherein the second converting unit comprises a second thermoelectric unit electrically connected to the power storage device, the second thermoelectric unit has substantially a same structure as that of the first thermoelectric unit and comprises a second hot side and a second cold side, the main body comprises a heat source, the second hot side is substantially located on or near the heat source to absorb and gather generated heat, and the second cold side is located away from the heat source to form a temperature difference between the second hot side and the second cold side, so that the second thermoelectric unit generates a constant current and the electrical energy is stored in the power storage device.

6. The protective container as claimed in claim 5, wherein the second thermoelectric unit is a thin-film thermoelectric component, and the hot side of the thermoelectric component is mounted on the heat source.

7. The protective container as claimed in claim 1, further comprising a photoelectric converting device electrically connected to the power storage device, wherein the photoelectric converting device comprises a plurality of solar panels located at the outer surface of sidewalls of the main body to absorb light energy from the sun to generate electrical energy, and the electrical energy is stored within the power storage device.

8. The protective container as claimed in claim 1, wherein the power storage device comprises a storage battery storing electrical energy from the first converting unit and the second converting unit.

9. The protective container as claimed in claim 8, wherein the power storage device further comprises a current converting unit electrically connected to the storage battery, the current converting unit is an inverter converting direct current from the thermoelectric converting device and the photoelectric converting device into alternating current.

10. The protective container as claimed in claim 9, wherein the power storage device further comprises a voltage converting unit connected to the current converting unit, the voltage converting unit converting output voltage from the current converting unit into different voltages for the electrical devices within the main body.

11. The protective container as claimed in claim 10, wherein the power storage device further comprises a filtering unit electrically connected to the voltage converting unit, the filtering unit rectifying and filtering output current from the voltage converting unit to generate and output a stable current to power the electrical devices.

12. A protective container, comprising:
a main body;
a thermoelectric converting device comprising:
a first converting unit located outside of the main body, the first converting unit comprising:
a first hot side located outside of the main body;
a first cold side installed and received within the main body; and
a convex lens assembly located outside the main body; and
a second converting unit received within the main body for converting heat in the main body into electrical energy; and
a photoelectric converting device located at an outer surface of the main body for using light energy to generate electrical energy; and
a power storage device electrically connected to the first converting unit, the second converting unit, and the photoelectric converting device, wherein the first hot side is aligned with the focus of the convex lens assembly, the convex lens assembly converges light lines to heat the first hot side and form a temperature difference between the first hot side and the first cold side, the first converting unit generates current, the electrical energy from the first converting unit, the second converting unit, and the photoelectric converting device is stored in the power storage device to provide voltages.

13. The protective container as claimed in claim 12, wherein the first hot side and the first cold side form a thermocouple consisting of a coupling or junction of dissimilar semiconductors or metals joined, two junction surfaces of contact are respectively used as the first hot side and the first cold side, and a temperature difference between the first hot side and the first cold side creates a current in the first thermoelectric unit.

14. The protective container as claimed in claim 12, wherein the convex lens assembly comprises a plurality of convex lenses, the foci of the convex lenses are aligned with the first hot side of the first thermoelectric unit, the convex lens assembly converges and focuses incoming light lines to the first hot side to increase the temperature of the first hot side thereby forming a temperature difference between the first hot side and the first cold side, so that current is generated in the first thermoelectric unit, and the electrical energy is stored in the power storage device.

15. The protective container as claimed in claim 12, wherein the second converting unit comprises a second thermoelectric unit electrically connected to the power storage device, the second thermoelectric unit has substantially a same structure as that of the first thermoelectric unit and comprises a second hot side and a second cold side, the main body comprises a heat source, the second hot side is substantially located on or near the heat source to absorb and gather generated heat, and the second cold side is located away from the heat source to form a temperature difference between the second hot side and the second cold side, so that the second thermoelectric unit generates a constant current, and the electrical energy is stored in the power storage device.

16. The protective container as claimed in claim 12, wherein the photoelectric converting device comprises a plurality of solar panels located at the outer surface of sidewalls of the main body to absorb light energy from the sun to generate electrical energy, and the electrical energy is stored within the power storage device.

17. The protective container as claimed in claim 12, wherein the power storage device comprises a storage battery storing electrical energy from the first converting unit and the second converting unit.

18. The protective container as claimed in claim 17, wherein the power storage device further comprises a current converting unit electrically connected to the storage battery, the current converting unit is an inverter converting direct current from the thermoelectric converting device and the photoelectric converting device into alternating current.

19. The protective container as claimed in claim 18, wherein the power storage device further comprises a voltage converting unit connected to the current converting unit, the voltage converting unit converting output voltage from the current converting unit into different voltages for electrical devices within the main body.

20. The protective container as claimed in claim 19, wherein the power storage device further comprises a filtering unit electrically connected to the voltage converting unit, the filtering unit rectifying and filtering output current from the voltage converting unit to generate and output a stable current to power the electrical devices.
